(19) United States
(12) Patent Application Publication
(10) Pub. No.: US 2023/0411302 A1
(43) Pub. Date: Dec. 21, 2023

(54) DEEP TRENCH BYPASS CAPACITOR FOR ELECTROMAGNETIC INTERFERENCE NOISE REDUCTION

(71) Applicant: TEXAS INSTRUMENTS INCORPORATED, Dallas, TX (US)

(72) Inventors: James Todd, Plano, TX (US); Archana Venugopal, Mountain View, CA (US)

(73) Assignee: TEXAS INSTRUMENTS INCORPORATED, Dallas, TX (US)

(21) Appl. No.: 17/806,954

(22) Filed: Jun. 15, 2022

(51) Int. Cl. H01L 23/552; H01L 27/06; H01L 49/02

(52) U.S. Cl. CPC H01L 23/552; H01L 27/0629; H01L 28/91

(57) ABSTRACT

A semiconductor device is described here. The semiconductor device includes a buried layer of a first conductivity type disposed on a semiconductor substrate. The semiconductor device includes a deep trench bypass capacitor extending into the buried layer and terminating in the buried layer. The deep trench bypass capacitor of the semiconductor device includes a first doped region, a dielectric disposed around the first doped region, and a second doped region disposed around the dielectric.

### TECHNICAL FIELD

Examples of the present disclosure generally relate to semiconductor devices and, in particular, to semiconductor devices with bypass capacitors for electromagnetic interference noise reduction.

### BACKGROUND

As the demand for faster, smaller electronic products with increased functionality is increased, stacked packaging schemes, such as package-on-package packaging, have become increasingly popular. The stacking of different semiconductor packages using stacked packages typically reduces the required footprint size for a semiconductor package in an electronic product. Furthermore, stacked packages can provide a modular solution for constructing electronic devices by permitting different combinations of stacked semiconductor packages using only a few semiconductor package footprints.

Many advanced electronic packages and devices typically include analog and digital circuits in the same electronic device or system. In these so-called “mixed-signal” devices, signals are typically susceptible to degradation as the signals traverse the various components of the electronic device. Furthermore, the analog signals are generally susceptible to electromagnetic interference (EMI) and the presence of digital signals in the vicinity of the analog components. This susceptibility generally allows the EMI from the digital circuits to couple directly into the analog sections of the mixed-signal device, generally resulting in noise being introduced into the analog signals.

For example, even though typical complementary metal-oxide-semiconductor (CMOS) digital devices in a high speed digital circuit generally have a low quiescent current, simultaneous switching noise (SSN, also known as ground bounce) caused by the CMOS circuit switching current, can be a significant source of EMI to the analog section of mixed signal device leading to increased noise. Additionally, some analog signals can be susceptible to EMI caused by high level signals from other analog circuits, particularly those which swing nearly a full supply voltage range, also resulting in increased noise.

In another example, EMI is a known problem with switching regulators. Often when switching regulators form a part of a system including wireless modules (e.g., mobile phones), EMI can interfere with receiver performance. Some solutions to addressing and mitigating EMI include board level solutions by reducing parasitic capacitance or wafer-level solutions by introducing bypass capacitors close to the package or even above the package.

### SUMMARY

This summary is provided to introduce a brief selection of disclosed concepts in a simplified form that are further illustrated and described below. This summary is not intended to limit the scope of the claimed subject matter. Disclosed aspects include semiconductor devices and fabrication methods therefor.

According to some examples, a semiconductor device includes a buried layer of a first conductivity type on a semiconductor substrate. The semiconductor device includes a deep trench bypass capacitor extending into the buried layer and terminating in the buried layer. The deep trench bypass capacitor of the semiconductor device includes a first doped region, a dielectric disposed around the first doped region, and a second doped region disposed around the dielectric.

According to some examples, a method for manufacturing a semiconductor device includes forming a buried layer on a semiconductor substrate, the buried layer having a first conductivity type. The method includes forming a semiconductor layer on the buried layer. The method includes forming a transistor at the semiconductor layer. The method includes forming a deep trench bypass capacitor adjacent to the transistor, the deep trench bypass capacitor comprising a deep trench, the deep trench filled with a polysilicon region, a dielectric region around the polysilicon region, and a doped region around the dielectric region, the deep trench bypass capacitor extending down from a first surface of the semiconductor layer and terminating in the buried layer.

According to some examples, a semiconductor device includes a buried layer disposed on a semiconductor substrate, the buried layer having a first conductivity type. The semiconductor device includes a semiconductor layer disposed on the buried layer. The semiconductor device includes a transistor disposed at the semiconductor layer. The semiconductor device includes an isolation deep trench extending through the semiconductor layer and into the semiconductor substrate. The semiconductor device includes a first bypass capacitor extending through the semiconductor layer and into the buried layer and terminating in the buried layer, the first bypass capacitator disposed between the transistor and the isolation deep trench.

### BRIEF DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 is a cross-sectional view of an integrated circuit semiconductor device that includes isolation deep trenches and deep trench bypass capacitators, according to some examples.

FIG. 2 is a cross-sectional view of an integrated circuit semiconductor device that includes isolation deep trenches and deep trench bypass capacitators, according to some examples.

FIG. 3 is a top view of an integrated circuit semiconductor device having isolation deep trenches and deep trench bypass capacitors, according to some examples.

FIG. 4 is a graph illustrating capacitance of various semiconductor devices, with different bypass capacitors, according to some examples.

FIG. 5 is a flow diagram showing operations for making a semiconductor device having a deep trench bypass capacitor, according to some examples.

FIG. 6A-6G are cross-sectional views of the making of a semiconductor device having a deep trench bypass capacitor, according to some examples.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the description or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

In the following discussion and in the claims, the terms “including”, “includes”, “having”, “has”, “with”, or variants thereof are intended to be inclusive in a manner similar to the term “comprising”, and thus should be interpreted to mean “including, but not limited to . . . ” Also, the term “couple” or “couples” is intended to include indirect or direct electrical or mechanical connection or combinations thereof. For example, if a first device couples to or is coupled with a second device, that connection may be through a direct electrical connection, or through an indirect electrical connection via one or more intervening devices and connections. The various features of the disclosed examples can be used in connection with a variety of different semiconductor devices, including without limitation integrated circuits having multiple electronic components, as well as single component semiconductor devices (e.g., single transistor products, single diode products, etc.).

Example devices and fabrication methods provide process integration for deep trench bypass capacitors to mitigate electromagnetic interference (EMI) at a transistor level. In some examples, the trenches are etched, deep doped regions surrounding the trenches are implanted, and the trenches are lined and filled using a thick photoresist and hard mask patterned with openings for capacitor trenches. Described examples facilitate forming deep trench bypass capacitors that mitigate EMI.

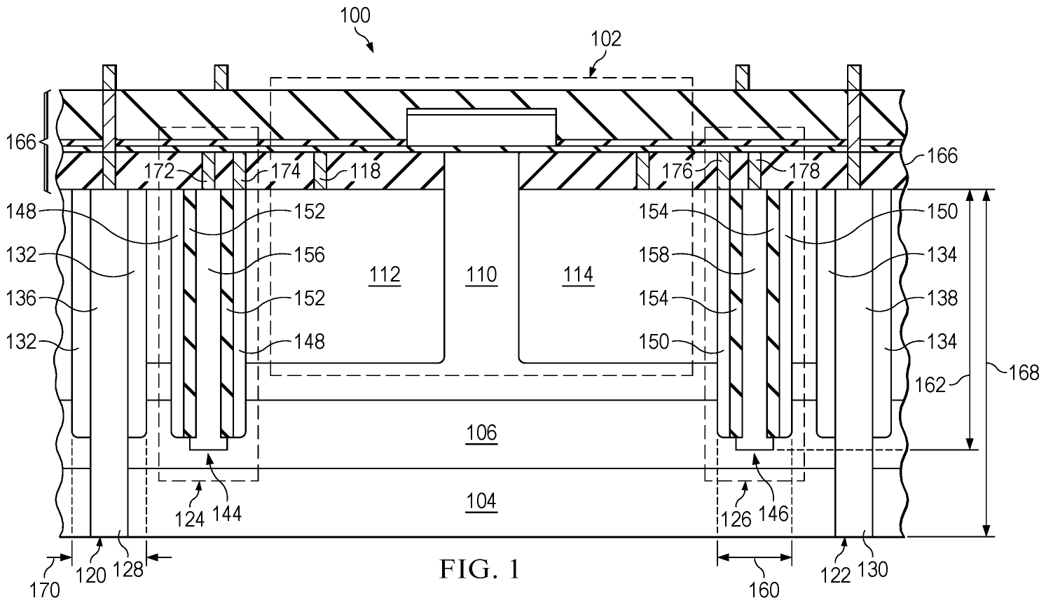

FIG. 1 shows an example integrated circuit semiconductor device 100 that includes a metal oxide semiconductor (MOS) transistor 102. Disclosed examples can also include stand-alone discrete transistor semiconductor devices that have a single transistor. The transistor 102 in FIG. 1 have single gate, source and drain finger structures (not illustrated). In other examples, transistors can be built with multiple finger structures surrounding a center finger, such as source-centered configurations, drain-centered configurations, etc. The examples described in the present disclosure can be implemented in combination with any type or form of transistor, such as MOS transistors bipolar transistors, etc. In addition, various aspects of the disclosure can be used in combination with drain extended MOS transistors (not shown). Described examples include doped regions of various semiconductor structures which may be characterized as p-doped and/or n-doped regions or portions, and include regions that have majority carrier dopants of a particular type, such as n-type dopants or p-type dopants.

The transistor 102 is fabricated on and/or in a semiconductor substrate 104. The semiconductor substrate 104 in one example is a silicon substrate, a silicon-on-insulator (SOI) substrate, or other semiconductor structures. In one example, the substrate 104 is a p-doped silicon substrate, with a first (e.g., top) side, a buried layer 106 formed therein, and a second (e.g., bottom) side opposite the first side. Accordingly, the buried layer 106 is disposed on or along the first side of the semiconductor substrate 104. In another example, the substrate 104 includes one or more epitaxial silicon layers (not shown) formed on a top surface (or the first side of the substrate 104), with one or more of the buried layers 106 formed in epitaxial layers of the substrate. In the illustrated example, the substrate 104, the buried layer 106, and an upper semiconductor surface layer (e.g., semiconductor layer 110) constitute the semiconductor device 100.

The example semiconductor device 100 includes a buried layer 106 (e.g., an n-type buried layer or NBL) that includes n-type majority carrier dopants (referred to as NBL 106). The NBL 106 extends along the vertical Z direction from the semiconductor substrate 104 toward the semiconductor layer 110. The NBL 106 has a first side and a second side, the second side opposite the first, and the second side of the NBL 106 is disposed adjacent to and/or along the first side of the semiconductor substrate 104.

The example semiconductor device 100 includes an semiconductor layer 110. The semiconductor layer 110 is disposed on the NBL 106 opposite the semiconductor substrate 104. In some examples, the semiconductor layer 110 includes a first side and a second side, the second side opposite the first side, and the second side of the semiconductor layer 110 is disposed adjacent to and/or along the first side of the NBL 106.

Although not shown, as known in the art, the semiconductor device 100 can include field oxide such as shallow trench isolating (STI) or local oxidation of silicon (LOCOS) in the semiconductor layer 110 for isolating adjacent devices.

The example semiconductor structure 100 includes doped region 112 and doped region 114. (e.g., n-type doped wells). As illustrated, the doped regions 112 and 114 extend along the vertical Z direction into the semiconductor layer 110 from the first side of the epitaxial layer. In some examples, the doped regions 112 and 114 each have a first side and a second side, the second side opposite the first side, and the second sides of the doped regions 112 and 114 are disposed adjacent to and/or along the first side of the semiconductor layer 110. In one example, an epitaxial silicon layer is formed over the upper surface of a silicon wafer substrate 104, and the semiconductor layer 110 is implanted with n-type dopants (e.g., phosphorus, etc.) to form the doped regions 112, 114.

The example semiconductor device 100 includes a dielectric layer 116. In one example, the dielectric layer 116 is a pre-metal dielectric (PMD) layer disposed over the transistor 102 and the semiconductor layer 110, opposite the NBL 106. In some examples, the dielectric layer 116 has a first side and a second side, the second side opposite the first side, and the second side of the dielectric layer 116 is disposed adjacent to and/or along the doped regions 112, 114. In one example, the dielectric layer 116 includes silicon dioxide (SiO₂) deposited over the transistor 102 and the semiconductor layer 110.

The dielectric layer 116, as a PMD dielectric layer, includes contact structures 118 (e.g., tungsten) that provide direct electrical connection (e.g., direct contact or connection through a silicide layer such as CoSi₂, not shown) to one or more features of the transistor 102. The dielectric layer 116 is formed over the semiconductor layer 110, with contact structure 118 formed therein to provide electrical interconnection access for one or more further upper metallization layers. In one example, a silicide is formed over the top surfaces of the source, drain and gate electrode structures of the transistor 102, and over the tops of the polysilicon features and to the deep doped regions 112, 114. Contacts 118 of the dielectric layer 116 are connected to the doped regions 112, 114, to the isolation deep trenches 120, 122 and the capacitors 124, 126. The metallization structure 166 covers the transistor 102 and provides internal and/or external electrical interconnection to the transistor source, drain and gate terminals (not illustrated) of the transistor 102.

The transistor 102 are formed on or in the semiconductor layer 110. In some examples, the semiconductor device 100 can include an outer oxide isolation structure that encircles the transistor 102 along the first (e.g., top) side in the semiconductor layer 110. The oxide structure, in one example, is a STI structure, which is disposed laterally outward of the transistor 102.

The illustrated semiconductor device 100 includes a trench-based bypass capacitor (e.g., trench-based bypass capacitor 124, trench-based bypass capacitor 126), referred to as a deep trench bypass capacitor. The deep trench bypass capacitors 124, 126 can be coupled to a ground voltage, by virtue of the trench bypass capacitor being a bypass capacitor designed to mitigate EMI. A semiconductor device can have any number of deep trench bypass capacitors disposed in any location or arrangement. For purposes of illustration, only two deep trench bypass capacitors are shown, but it is understood more than two deep trench bypass capacitors are generally formed. In some examples, the deep trench bypass capacitor(s) 124, 126 can have any shape, such as a circular cylinder or hexagonal cylinder (also referred to as a hexagonal prism). In some examples, the deep trench bypass capacitors 124, 126 can form planes that intersect the buried layer 106 of the semiconductor device 100 and with an edge of the respective plane that terminates in the buried layer 106.

The deep trench bypass capacitor 124 in FIG. 1 is disposed adjacent to the transistor 102, and in some examples, the deep trench bypass capacitor 124 is also disposed adjacent to the isolation trench 120. Similarly, the deep trench bypass capacitor 126 is disposed adjacent to the transistor 102, and in some examples, the deep trench bypass capacitor 126 is also disposed adjacent to the isolation deep trench 122. Accordingly, a deep trench bypass capacitor 124, 126 can laterally encircle or surround the transistor 102. For example, the deep trench bypass capacitors 124, 126 can have a ring shape and thus encircle or surround the transistor 102, and accordingly the deep trench bypass capacitors 124, 126 shown in FIG. 1 are cross-sections of the same deep trench bypass capacitor. In other examples, the deep trench bypass capacitors 124, 126 are separate and can any shape or size, and accordingly, the deep trench bypass capacitors 124, 126 shown in FIG. 1 can be cross-sections of different deep trench bypass capacitors.

While FIG. 1 illustrates deep trench bypass capacitors 124, 126 disposed adjacent to the transistor 102, other examples of the semiconductor device can have the deep trench bypass capacitors 124, 126 disposed anywhere on a semiconductor device 100 to mitigate EMI.

The deep trench bypass capacitors 124, 126 each includes a trench region 144, 146 that extends downward from the first side of the semiconductor layer 110 and terminating in the buried layer 106. Accordingly, the deep trench bypass capacitors 124, 126 extend through the semiconductor layer 110 and into the buried layer 106, and terminate in the buried layer 106.

The deep trench bypass capacitor 124, 126 also includes a deep doped region 148, 150 with n-type majority carrier dopants (e.g., a deep n-type well). The deep doped region 148, 150 surrounds the trench region 144, 146 and extends from first side of the semiconductor layer 110 to the buried layer 106. In some examples, the deep doped region 148, 150 comprises the cathodes of the respective deep trench bypass capacitors 124, 126.

The deep trench bypass capacitors 124, 126 also include a dielectric 152, 154 that extends along the sidewall of the trench region 144, 146 of the respective deep trench bypass capacitor 124, 126 from the semiconductor layer 110 to the buried layer 106. Any single or multilayer dielectric can be used with any of the deep trench bypass capacitors. In some example, the dielectric 152, 154 includes an oxide (e.g., silicon dioxide or SiO₂) layer, a nitride (e.g., silicon nitride or silicon oxynitride) layer, and/or any combination thereof. The dielectric 152, 154 can have a higher dielectric constant than silicon dioxide.

The deep trench bypass capacitor 124, 126 also includes a polysilicon 156, 158 that extends inside the dielectric 152, 154. The polysilicon 156, 158 fills the trench region 144, 146 of the respective deep trench bypass capacitors 124, 126 to the top side of the semiconductor layer 110. While the deep trench bypass capacitors 124, 126 include a polysilicon 156, 158, the polysilicon 156, 158 can be other trench fill material, such as amorphous silicon, or semi-amorphous silicon. The polysilicon 156, 158, in one example, includes p-type majority carrier dopants (e.g., boron). For example, the polysilicon 156, 158 can have an average concentration of dopants of 5×10¹⁸ atoms/cm³ and 1×10²⁰ atoms/cm³. The deep trench bypass capacitor 124, 126 is formed as a ring structure that laterally surrounds the transistor 102. In one example, the deep trench bypass capacitors 124, 126 can be constructed using a single trench. In some examples, the polysilicon 156, 158 comprises the anodes of the respective deep trench bypass capacitors 124, 126.

While the examples above describe a deep doped region 148, 150 and a polysilicon 156, 158 for the deep trench bypass capacitors 124, 126, the deep trench bypass capacitors 124, 126 can include metal regions instead of the deep doped region 148, 150 and a polysilicon 156, 158. For example, the deep trench capacitors 124, 126 includes a first metal region (in place of the deep doped region 148, 150), a second metal region (in place of the polysilicon 156, 158), and the dielectric 152, 154 between the first metal region and the second region.

As shown in FIG. 1, the trench 144, 146 has a depth 162 and a width 160. The depth 162 of the trenches 144, 146 measures from the top side of the semiconductor layer 110 to the terminating end of the trenches 144, 146 disposed in the buried layer 106. In some examples, the width 160 of the trenches 144, 146 refers to and measures the inner diameter of the polysilicon region 156, 158 of the deep trench bypass capacitors 124, 126. The inner diameter of the polysilicon 156, 158 is the diameter of the polysilicon 156, 158 measured at the first side of the semiconductor layer 110. In one example, the width 160 of the polysilicon 156, 158 of the deep trench bypass capacitors 124, 126 can range from 1.05 μm to 1.7 μm; and the depth 162 of the deep trench bypass capacitor 124, 126 can range from 16 um to 25 μm. For example, the width 160 of the polysilicon 156, 158 of the deep trench bypass capacitors 124, 126 is approximately 1.7 μm, and the depth of the deep trench bypass capacitors 124, 126 is 25 μm. In one example, the width 160 of the polysilicon 156, 158 of the deep trench bypass capacitors 124, 126 is 1.4 μm, and correspondingly the depth of the deep trench bypass capacitors 124, 126 is 22 μm. In yet another example, the width 160 of the polysilicon region 156, 158 of the deep trench bypass capacitors 124, 126 is 1.2 μm, and the depth of the deep trench bypass capacitors 124, 126 is 16 μm. The inner width 160 of the deep trench bypass capacitor 124, 126 can be based on the depth 162 of the deep trench bypass capacitor. In some examples, the inner width 160 of the deep trench bypass capacitor 124, 126 is between 0.01 times the depth 162 of the deep trench bypass capacitor 124, 126 and 0.1 times the depth 162 of the deep trench bypass capacitor 124, 126.

In some examples, because of the nature of trench etching, the width 160 of the deep trench bypass capacitors 124, 126 can be different along the first side of the semiconductor layer 110 compared to the terminating end located in the buried layer 106. The difference between the widths of the polysilicon region 156, 158 of the deep trench bypass capacitors 124, 126 occurs because of the etching process. For example, the inner diameter of the polysilicon 156, 158 of the deep trench bypass capacitors 124, 126 measures 1.7 um at the first side of the semiconductor layer 110 and measures 0.04 um at the terminating end located in the buried layer 106. Because of the difference in the width 160 of the deep trench bypass capacitors 124, 126 at the first side of the semiconductor layer 110 and at the terminating end locating in the buried layer 106, the respective capacitance at the first side of the semiconductor layer 110 and at the terminating end locating in the buried layer 106. Accordingly, the capacitance of the deep trench bypass capacitors 124, 126 ranges from 1.3 fF to 8.34 fF.

In some examples, as illustrated, the semiconductor device 100 includes an isolation deep trench (e.g., isolation deep trench 120, isolation deep trench 122). As illustrated in FIG. 1, the isolation deep trench 120 in FIG. 1 is disposed adjacent to a deep trench bypass capacitor 124, and the isolation deep trench 122 is disposed adjacent to a deep trench bypass capacitor 126. The semiconductor device 100 can include any number of isolation deep trenches and any arrangement of the isolation deep trenches. For purposes of illustration, only two isolation deep trenches are shown, but it is understood more than two isolation deep trenches (such as tens of thousands or hundreds of thousands of trenches) are generally formed. Discussion of the isolation deep trench can refer to either isolation deep trench 120 or isolation deep trench 122, and any specific discussion with regards to one isolation deep trench can apply to any and/or all isolation deep trenches.

Each of the isolation deep trenches 120, 122 includes a trench region 128, 130 that extends downward from a first side of the semiconductor layer 110, through the buried layer 106, and through the semiconductor substrate 104. The trench region 128, 130 of the isolation deep trenches 120, 122 can terminate at the second side of the semiconductor substrate 104, the second side being opposite of the first side adjacent to the buried layer 106.

The isolation deep trenches 120, 122 also include a deep doped region 132, 134 with n-type majority carrier dopants. The deep doped regions 132, 134 surround the respective first trench 128, 130 and extends from the first side of the semiconductor layer 110 into the buried layer 106. In some examples, the deep doped regions 132, 134 terminate in the buried layer 106, and in other examples, the deep doped region 132, 134 extend into the semiconductor substrate 104 and have the same depth as the trench regions 128, 130.

Each of the isolation deep trenches 120, 122 also includes a dielectric liner (not illustrated) that extends along the sidewall of the trenches 128, 130 from the first side of semiconductor layer 110 to the semiconductor substrate 104. Any single or multilayer dielectric liner can be used. In one example, the dielectric liner includes an oxide layer, a nitride layer, and/or any combination thereof. The oxide layer can extend along the sidewall of the trench regions 128, 130 from the first side of semiconductor layer 110 to the semiconductor substrate 104. The nitride layer can extend along the oxide layer from the first side of semiconductor layer 110 to the semiconductor substrate 104.

The isolation deep trenches 120, 122 also includes a polysilicon 136, 138 that extends inside the dielectric liner of the trench regions 128, 130. The polysilicon 136, 138 fills the trench region 128, 130 of each respective isolation deep trench 120, 122 to the top side of the semiconductor layer 110. The polysilicon 136, 138 in one example includes p-type majority carrier dopants.

The isolation deep trench 120, 122 can be formed as a ring structure that laterally surrounds the transistor 102. As shown in FIG. 1, each of the trench 128, 130 has a depth 168 and a width 170. The width 170 of the isolation trench 120, 122 can be greater than the width 160 of the deep trench bypass capacitor 124, 126. In one example, the width 170 of the isolation trench 120, 122 can range from 1.35 μm to 1.65 μm, for example, approximately 1.5 μm. Similarly, the depth 168 of the isolation trench 120, 122 can be greater than the depth of the deep trench bypass capacitor 124, 126.

In some examples, the semiconductor device 100 includes a metallization structure 166 that extends over the semiconductor layer 110. As illustrated, the metallization structure 166 extends over the dielectric layer 116. The metallization structure 166 includes conductive features that connect isolation deep trenches 120, 122 to other circuitry within the wafer or die, and/or to provide external connections. The metallization structure 166 also includes conductive features that connect the deep trench bypass capacitors 124, 126 to other circuitry within the wafer or die, and/or to provide external connections. For example, the metallization structure 166 includes conductive features that connect the polysilicon 156, 158 of the deep trench bypass capacitor 124, 126 to the other circuitry or to external circuitry. As illustrated, the conductive features of the metallization structure 166 includes a first contact 172, 176 to the respective polysilicon 156, 158 of the deep trench bypass capacitors 124, 126. The conductive features of the metallization structure 166 includes a second contact 174, 178 to the respective polysilicon 156, 158 of the deep trench bypass capacitors 124, 126. The metallization structure 166 can include any number of metallization layers and any number of dielectric layers disposed on the semiconductor layer 110 and on the dielectric layer 116. Any number of conductive features may be provided. One or more of the conductive features can be electrically coupled with an electronic component, such as the transistor 102.

In some examples, the semiconductor device 100 can include one or more passivation layers (not illustrated) (e.g., protective overcoat (PO) and/or passivation layers), for example, silicon nitride (SiN), silicon oxynitride (SiOₓN_{y}), or silicon dioxide (SiO₂). In one example, the passivation layer or layers include one or more openings that expose a portion of the conductive features to allow electrical connection of the features of the semiconductor device 100 to corresponding contact structures.

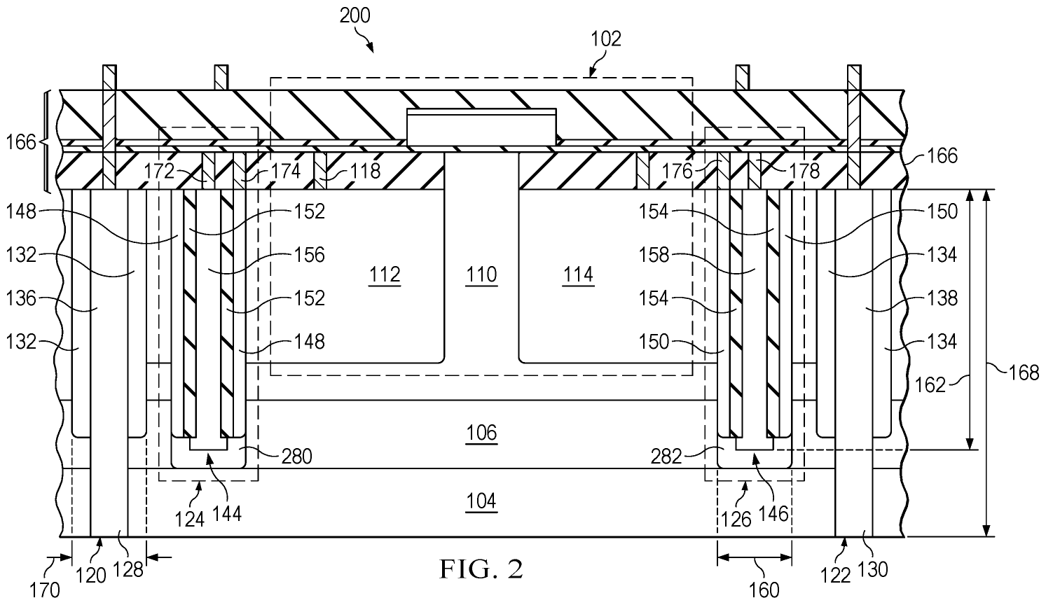

FIG. 2 is a cross-sectional view of an integrated circuit semiconductor device that includes isolation deep trenches and deep trench bypass capacitators, according to some examples. Specifically, the integrated circuit semiconductor device 200 includes similar features as the semiconductor device 100 of FIG. 1. The semiconductor device 200 includes deep phosphorus implants 280, 282 for the deep trench bypass capacitors 124, 126.

The deep trench bypass capacitor 124, 126 includes a deep phosphorus implant 280, 282 respectively that extends along the sides of the deep trench bypass capacitors 124, 126. In some examples, the deep phosphorus implants 280, 282 are disposed at the terminating ends of the deep trench bypass capacitors 124, 126. The deep phosphorus implants 280, 282 of the deep trench bypass capacitors 124, 126 can be disposed in the buried layer 106. In some examples, the deep phosphorus implants 280, 282 can extend along the sides of the trench region 144, 146 of the deep trench bypass capacitors 124, 126. The deep phosphorus implants 280, 282 can also extend through the buried layer 106 to the substrate 104.

The deep phosphorus implants 280, 282 comprises silicon with phosphorus dopants. For example, the deep phosphorus implants 280, 282 can have a range of concentration of dopants between 1×10¹⁵ cm⁻³ and 1×10¹⁰ cm⁻³, such as 1×e¹⁶ atoms/cm³, to provide a low equivalent series resistance for the deep trench bypass capacitor 124, 126.

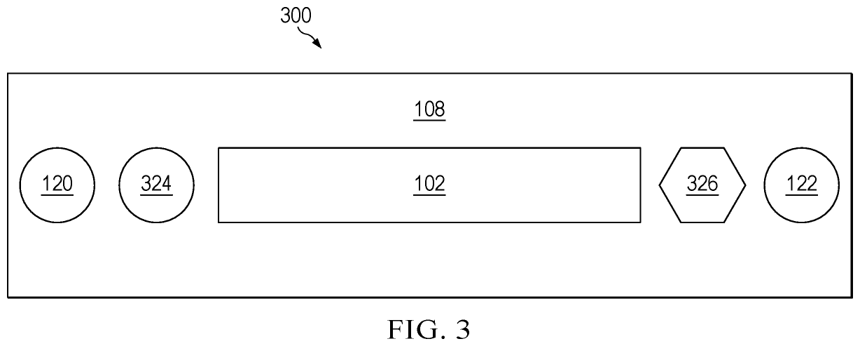

FIG. 3 is a top view of an integrated circuit semiconductor device having isolation deep trenches and deep trench bypass capacitors, according to some examples. Specifically, FIG. 3 illustrates a top cross-sectional view of the semiconductor layer 110 of the integrated circuit semiconductor device 300 without a metallization structure (e.g., metallization structure 166 of FIG. 1) disposed on the semiconductor layer 110.

The integrated circuit semiconductor device 300 includes a transistor 102, which has similar features as the transistor 102 of FIG. 1. The integrated circuit semiconductor device 300 includes features of the semiconductor device 100, such as isolation deep trenches 120, 122. The isolation deep trenches 120, 122 of FIG. 3 can the isolation deep trenches 120, 122 of FIG. 1.

The integrated circuit semiconductor device 300 also includes deep trench bypass capacitors 324, 326, like the deep trench bypass capacitors 124, 126 of FIG. 1. The deep trench bypass capacitors 324, 326 have similar features as the deep trench bypass capacitors 124, 126, and the deep trench capacitors 324, 326 are depicted in FIG. 3 to show the different cross-sectional shapes that any deep trench bypass capacitor can have. Accordingly, any deep trench bypass capacitor or any portion thereof can have any cross-sectional shape, such as the circular cylindrical cross-section of deep trench bypass capacitor 324 and the hexagonal cylindrical cross-section of the deep trench bypass capacitor 326. Further, any deep trench bypass capacitor or any portion thereof can have a conical shape because the etching of the deep trench bypass capacitor may not be a vertical etch down to the intended depth and thus sides of the deep trench bypass capacitor are angled. A semiconductor device can have any combination of the deep trench bypass capacitors, with the deep trench bypass capacitors having any cross-sectional shape.

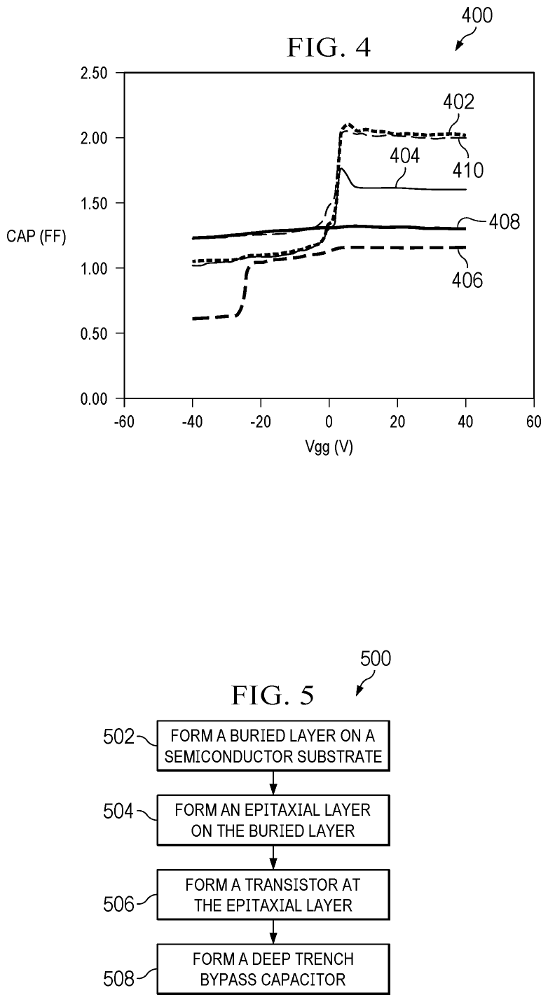

FIG. 4 is a graph illustrating capacitance of various semiconductor devices, with different bypass capacitors, according to some examples. The graph 400 illustrates results 402, 404, 406, 408, 410 each showing results of different deep trench bypass capacitors. Result 402 shows resulting capacitance of a deep trench bypass capacitor having a polysilicon region of an inner width of 1.7 um. Result 404 shows resulting capacitance of a deep trench bypass capacitor having a polysilicon region of an inner width of 1.4 um. Result 406 shows resulting capacitance of a deep trench bypass capacitor having a polysilicon region of an inner width of 1.2 um. Result 408 shows resulting capacitance of a deep trench bypass capacitor having a polysilicon region of an inner width of 1.2 um and having a deep phosphorus implant. Result 410 shows resulting capacitance of a deep trench bypass capacitor having a polysilicon region of an inner width of 1.7 um and having a deep phosphorus implant. As illustrated, as the inner width of the polysilicon regions 156, 158 of the respective deep trench bypass capacitor 124, 126 decreases, the capacitance of the deep trench bypass capacitors 124, 126 becomes more consistent going from negative voltages to positive voltages.

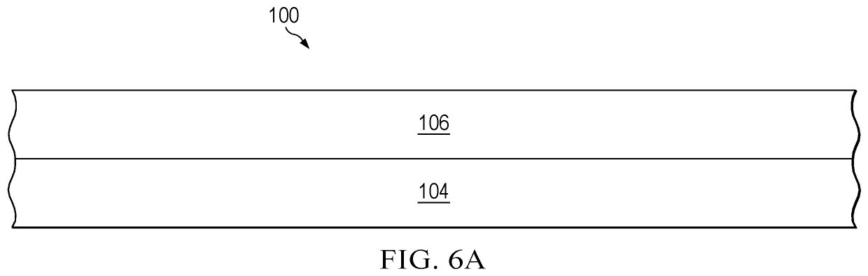

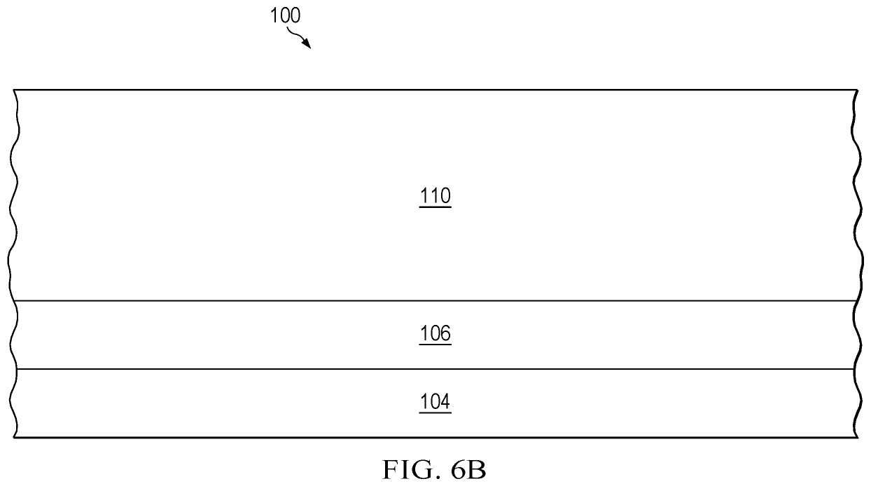

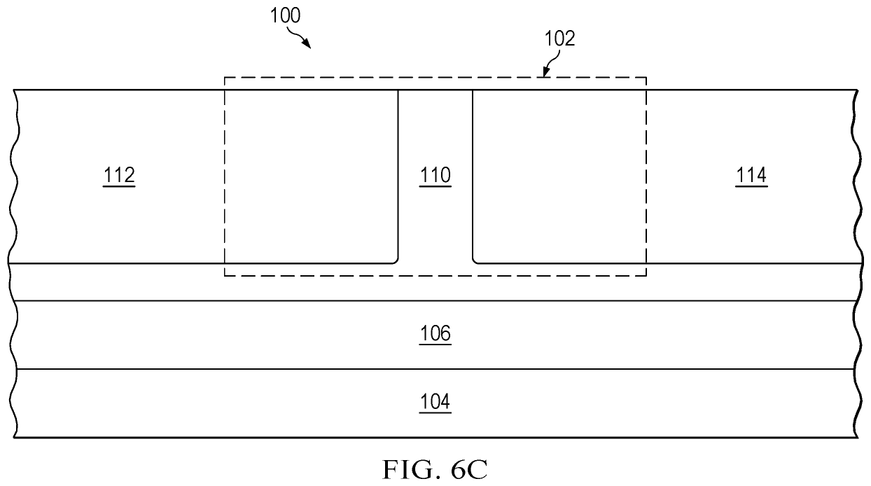

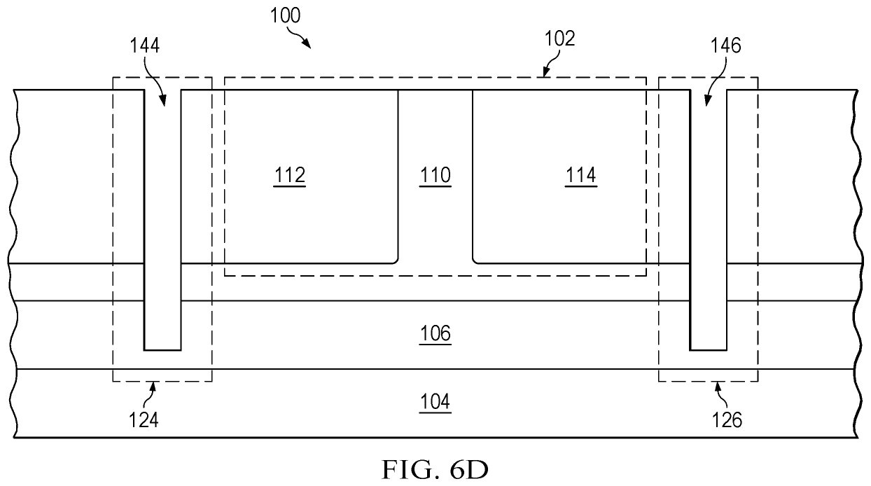

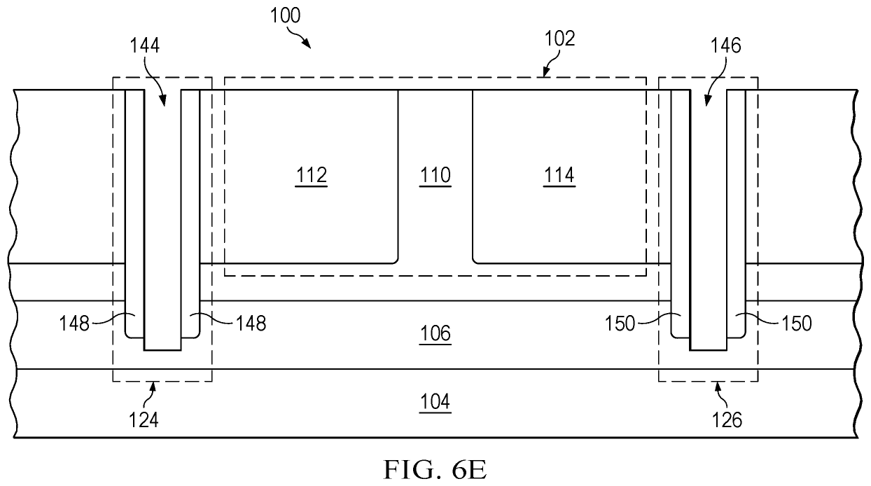

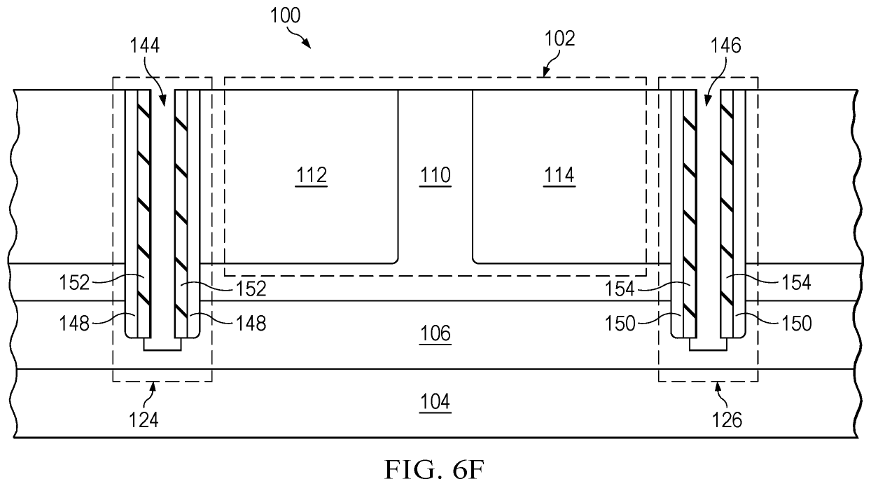

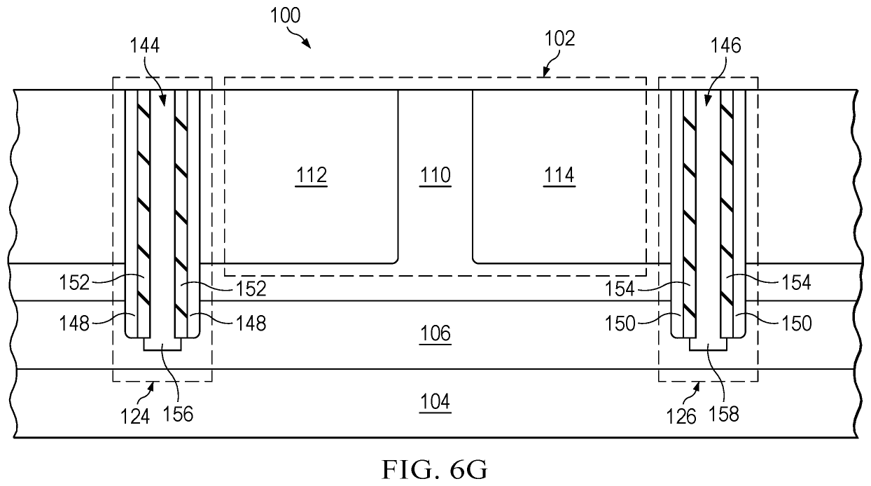

FIG. 5 is a flow diagram showing operations for making a semiconductor device having a deep trench bypass capacitor, according to some examples. Modifications are possible in the described embodiments, and other embodiments are possible, within the scope of the claims. FIGS. 6A-6G are cross-sectional views of the operations for making a semiconductor device with a deep trench bypass capacitor, according to the method 500 of FIG. 5.

The method 500 begins at 502 with a doping implantation to form a doped region, such as the NBL region 106 in FIG. 1, as shown in FIG. 6A. In one example, a epitaxial layer is formed over the first side of a silicon substrate 104, and the epitaxial layer is implanted with n-type dopants (e.g., Sb, etc.) at 502 to form the NBL 106. In another example, the substrate 104 is implanted with n-type dopant prior to forming the semiconductor layer 110. During formation of the semiconductor layer 110, the implanted dopant diffuses to form the NBL layer 106 at the interface of the substrate 104 and the semiconductor layer 110.

The method 500 continues at 504 with forming an epitaxial layer (e.g., semiconductor layer 110) on the first side of the NBL 106, as shown in FIG. 6B. The epitaxial layer provided with the wafer has a first conductivity type, and the buried layer provided with the wafer can have the same conductivity type as the epitaxial layer. The first conductivity type can be n-type in some examples, and in other examples, the first conductivity type can be p-type.

The method 500 continues at 506 with forming a transistor (e.g., transistor 102) at the epitaxial layer, as shown in FIG. 6C. Forming the transistor can involve forming structures of the transistor 102. In one example, the transistor formation includes performing an implantation process that implants dopants to form the shallow implant region extending along a side of the first trench 121 within the deep doped region 122. Accordingly, the formed transistor can be an NPN transistor or a PNP transistor.

The method 500 continues at 508 with forming a deep trench bypass capacitor (e.g., deep trench bypass capacitor 124, 126). Forming the deep trench bypass capacitor can involve any of the following: depositing and patterning a thick resist layer with openings for the deep trench bypass capacitors; overlaying photoresist layer on the semiconductor device; forming the trench region (e.g., trench region 144, 146) of the deep trench bypass capacitor, as illustrated in FIG. 6D; implanting one or more deep trench implantations to form the deep doped region (e.g., deep doped region 148, 150) surrounding the trench region of the deep trench bypass capacitors, as illustrated in FIG. 6E; forming the dielectric region (e.g., dielectric 152, 154) of the deep trench bypass capacitors, as illustrated in FIG. 6F; and forming polysilicon (e.g., polysilicon 156, 158) of the deep trench bypass capacitors, as illustrated in FIG. 6G. Other features of the semiconductor device illustrated in FIGS. 1 and 2 can be formed once the deep trench bypass capacitor is formed.

While the examples above describe forming a deep doped region and forming a polysilicon 156, 158 for the deep trench bypass capacitors 124, 126, the method for making a semiconductor device having a deep trench bypass capacitor can include forming the deep trench bypass capacitor with metal regions instead of the deep doped region 148, 150 and a polysilicon 156, 158. For example, the method for making a semiconductor device having a deep trench bypass capacitor can include forming a first metal region (in place of the deep doped region 148, 150), forming a second metal region (in place of the polysilicon 156, 158), and forming the dielectric 152, 154 between the first metal region and the second region.

In some examples, forming a deep trench bypass capacitor (step 508) includes depositing and patterning a thick resist layer with openings for the deep trench bypass capacitors 124, 126. In some examples, the thick resist layer includes openings for isolation deep trenches 120, 122. When depositing and patterning the thick resist layer with openings, the process includes depositing and patterning a resist mask over the hard mask layer on first side of the semiconductor layer 110 of the semiconductor device 100. The process, in one example, includes forming the resist layer and patterning the openings of the deep trench bypass capacitor 124, 126, as well as patterning any other openings for any other structures (e.g., the isolation deep trenches 120, 122).

In some examples, a photoresist layer overlies a dielectric layer that is generally a silicon oxide layer, which protects the surface of the semiconductor device 100. Although not shown, the photoresist layer can be on top of a hardmask (HM) layer, such as a high-density plasma oxide HM layer, that is formed on the dielectric layer. An oxide HM layer may be used when the photoresist layer is thin or the trench region 144, 146 of the deep trench bypass capacitors 124, 126 is deep enough so that the photoresist layer is completely destroyed in the trench etching process.

In some examples, etching is used to form the deep trench region 144, 146 through the oxide HM (if used), the dielectric layer (not illustrated), into the semiconductor layer 110, into the NBL 106, but not reaching the substrate 104. It will be understood that although the photoresist layer can remain intact after the trench etching, much of the photoresist layer may have been removed by the trench etch process. The photoresist layer is then removed and the wafer is cleaned.

In examples where the photoresist layer includes multiple openings for multiple deep trench bypass capacitors, the etch process concurrently etches through the multiple openings to form trench regions 144, 146 that extend into the NBL 106 for each of the deep trench bypass capacitors 124, 126.

In some examples, forming the deep trench bypass capacitor (step 508) further includes forming the deep doped region 122 surrounding the trench region 144, 146 of the deep trench bypass capacitors 124, 126 via one or more deep trench implantations. The method can also include one or more deep trench implantations to form deep doped regions surrounding trench regions 128, 130 of the isolation deep trenches 120, 122. The implantation process can involve using the remaining resist mask to concurrently implant n-type dopants through the openings of the resist mask to form the doped regions 132, 134. In some example, the implantation is an angled deep N trench sidewall implant. In some examples, a second implantation process is performed to implant the bottoms of the doped regions 132, 134. Such implantation process implants phosphorus or other n-type dopants through the resist openings to further implant the silicon below the bottoms of the trench region 144, 146 of the deep trench bypass capacitors 124, 126 at a dose of 1×e¹⁶ atoms/cm³.

The step 508 of forming the deep trench bypass capacitor of the method 500 further includes deposition processing to form dielectric (e.g., dielectric 116), disposed along the sidewalls of the trench region 144, 146 of the deep trench bypass capacitors 124, 126. A dielectric layer is grown or deposited on the sidewalls and the bottom of the trench regions 144, 146. In one aspect, the dielectric is entirely a silicon oxide. Any suitable dielectric can be used that forms a capacitor dielectric in the finished deep trench bypass capacitors 124, 126. The dielectric can be, for example, 0.1 um to 1 um thick, such as 0.54 um thick.

The step 508 of forming the deep trench bypass capacitor of the method 500 further includes depositing polysilicon (e.g., polysilicon 156, 158), generally by a low pressure chemical vapor deposition (LPCVD) process to fill the trench regions 144, 146 of the deep trench bypass capacitors 124, 126. In some examples, the polysilicon can be doped, e.g., p+ polysilicon, or n+ polysilicon, or be furnace doped.

In some examples, the method 500 can further include forming a mask layer for forming deep phosphorus implants. The mask layer for forming the deep phosphorus implants can be the same mask layer used for forming the deep trench bypass capacitors.

After forming the mask layer for forming the deep phosphorus implants, the method 500 can further include forming the deep phosphorus implants in the buried layer based on the formed mask layer. The formed deep phosphorus implants can have the same or similar features as the deep phosphorus implants 280, 282 of the deep trench bypass capacitors 124, 126 of FIG. 2. After the deep phosphorus implants are formed, the method 500 can further include removing the mask layer to finish processing the semiconductor device.

As mentioned earlier, the semiconductor device can include isolation deep trenches (e.g., isolation deep trenches 120, 122). Accordingly, in some examples, the method 500 can include forming a trench of an isolation deep trench simultaneously as forming the deep trench of the deep trench bypass capacitor. As shown in FIG. 1, each of the isolation deep trenches 120, 122 has a depth 168 and a width 170. The width 170 of the isolation deep trenches 120, 122 can be greater than the width 160 of the deep trench bypass capacitor 124, 126. Because of the larger width of the isolation deep trenches 120, 122 compared to the width of the deep trench bypass capacitor 124, 126, the depth 168 of the isolation deep trenches 120, 122 is greater than the depth of the deep trench bypass capacitor 124, 126 due to the etching process. Once the trench of the isolation deep trench is formed, the method 500 can include forming the dielectric and the dielectric liner of the isolation deep trench simultaneously as forming the dielectric of the deep trench bypass capacitor. Once the dielectric and the dielectric liner of the isolation deep trench are formed, the method 500 can further include forming a polysilicon region of the isolation deep trench simultaneously as forming the polysilicon region of the deep trench bypass capacitor.

The method 500 continues with BEOL processing and packaging of the semiconductor device

The invention has several important technical advantages. Various embodiments of the invention may have none, some or all of these advantages. One advantage may be that the manufacturing process is simpler and requires fewer structure steps. The simpler process may be used in analog capacitor fabrication. The semiconductor may also be a memory device with reduced cell size for memory arrays with higher density than existing single poly non-flash devices. Further, the present invention can easily be integrated into the current process flow with minimal changes. Other technical advantages of the present invention will be readily apparent to one skilled in the art.

The semiconductor die with disclosed trench capacitors may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can be formed from a variety of processes including bipolar, Insulated Gate Bipolar Transistor (IGBT), CMOS, bipolar CMOS (BiCMOS), and micro-electromechanical system (MEMS).

Although the invention has been illustrated and described with respect to one or more implementations, equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Unless otherwise stated, “about,” “approximately,” or “substantially” preceding a value means +/−10 percent of the stated value.

Although the present invention has been described in detail, it should be understood that various changes, substitutions and alterations can be made hereto without departing from the sphere and scope of the invention as defined by the appended claims.

To aid the Patent Office, and any readers of any patent issued on this application in interpreting the claims appended hereto, applicants wish to note that they do not intend any of the appended claims to invoke 35 U.S.C. § 112, ¶ 6 as it exists on the date of filing hereof unless “means for” or “step for” are used in the particular claim.

What is claimed:

1. A semiconductor device comprising:
a buried layer of a first conductivity type on a semiconductor substrate;
a deep trench bypass capacitor extending into the buried layer and terminating in the buried layer, the deep trench bypass capacitor comprising:
a first doped region;
a dielectric disposed around the first doped region; and
a second doped region disposed around the dielectric.

2. The semiconductor device of claim 1, wherein the dielectric extends between the first doped region and the buried layer.

3. The semiconductor device of claim 1, further comprising a semiconductor layer disposed on the buried layer, wherein the deep trench bypass capacitor extends through the semiconductor layer.

4. The semiconductor device of claim 1, wherein an inner width of the deep trench bypass capacitor is greater than about 1.2 μm.

5. The semiconductor device of claim 1, wherein an inner width of the deep trench bypass capacitor is between about 1.2 μm and 1.7 μm.

6. The semiconductor device of claim 1, wherein an inner width of the deep trench bypass capacitor is based on a depth of the deep trench bypass capacitor.

7. The semiconductor device of claim 1, wherein an inner width of the deep trench bypass capacitor is between 0.01 times a depth of the deep trench bypass capacitor and 0.1 times the depth of the deep trench bypass capacitor.

8. The semiconductor device of claim 1, wherein at least a portion of the deep trench bypass capacitor comprises a circular cylindrical capacitor.

9. The semiconductor device of claim 1, wherein at least a portion of the deep trench bypass capacitor comprises a hexagonal cylindrical capacitor.

10. The semiconductor of claim 1, wherein at least a portion of the deep trench bypass capacitor comprises a conical shape.

11. The semiconductor device of claim 1, further comprising deep phosphorus implants disposed in the buried layer and disposed around the dielectric region of the deep trench bypass capacitor.

12. The semiconductor device of claim 11, wherein the deep phosphorus implants have a doping concentration between 1×e¹⁵ to 1×e¹⁹.

13. The semiconductor device of claim 1, wherein the dielectric of the deep trench bypass capacitor has a higher dielectric constant than silicon dioxide.

14. The semiconductor device of claim 1, further comprising conductive features disposed in a metallization structure disposed on the deep trench bypass capacitor, the conductive features connected to the deep trench bypass capacitor.

15. The semiconductor device of claim 1, wherein the conductive features comprises a first contact coupled to the first doped region of the deep trench bypass capacitor; and a second contact coupled to the second doped region of the deep trench bypass capacitor.

16. The semiconductor device of claim 1, wherein the deep trench bypass capacitor is coupled to a ground voltage.

17. The semiconductor device of claim 1, wherein a width of the dielectric is between 0.1 μm and 1 μm.

18. A method for manufacturing a semiconductor device, the method comprising:
forming a buried layer on a semiconductor substrate, the buried layer having a first conductivity type;
forming a semiconductor layer on the buried layer;
forming a transistor at the semiconductor layer; and
forming a deep trench bypass capacitor adjacent to the transistor, the deep trench bypass capacitor comprising a deep trench, the deep trench filled with a polysilicon region, a dielectric region around the polysilicon region, and a doped region around the dielectric region, the deep trench bypass capacitor extending down from a first surface of the semiconductor layer and terminating in the buried layer.

19. The method of claim 18, further comprising:
forming a mask layer for forming deep phosphorus implants;
forming the deep phosphorus implants in the buried layer based on the mask layer, the deep phosphorus implants disposed around the polysilicon region of the deep trench bypass capacitor; and
removing the mask layer after forming the deep phosphorus implants.

20. The method of claim 18, further comprising:
forming a trench of an isolation deep trench simultaneously as forming the deep trench of the deep trench bypass capacitor;
forming the dielectric and a dielectric liner of the isolation deep trench simultaneously as forming the dielectric region of the deep trench bypass capacitor; and
forming polysilicon region of the isolation deep trench simultaneously as forming the polysilicon region of the deep trench bypass capacitor.

21. The method of claim 20, wherein a width of the deep trench of the deep trench bypass capacitor is less than a width of the trench of the isolation deep trench.

22. The method of claim 20, wherein a depth of the deep trench of the deep trench bypass capacitor is less than a depth of the trench of the isolation deep trench.

23. A semiconductor structure, comprising:
a buried layer disposed on a semiconductor substrate, the buried layer having a first conductivity type;
a semiconductor layer disposed on the buried layer;
a transistor disposed at the semiconductor layer;
an isolation deep trench extending through the semiconductor layer and into the semiconductor substrate; and
a first bypass capacitor extending through the semiconductor layer and into the buried layer and terminating in the buried layer, the first bypass capacitator disposed between the transistor and the isolation deep trench.

24. The semiconductor structure of claim 23, further comprising a second bypass capacitor extending through the semiconductor layer and into the buried layer and terminating in the buried layer, the second bypass capacitor adjacent to the transistor.

25. The semiconductor structure of claim 23, wherein the first bypass capacitor comprises a cathode, an anode, and a dielectric disposed between the cathode and the anode, wherein the dielectric is disposed around the anode, and the cathode is disposed around the dielectric.

26. A method for manufacturing a semiconductor device, the method comprising:
forming a buried layer on a semiconductor substrate, the buried layer having a first conductivity type;
forming a semiconductor layer on the buried layer;
forming a transistor at the semiconductor layer; and
forming a deep trench bypass capacitor adjacent to the transistor, the deep trench bypass capacitor comprising a deep trench, the deep trench including a first metal region, a dielectric region around the first metal region, and a second metal region around the dielectric region, the deep trench bypass capacitor extending down from a first surface of the semiconductor layer and terminating in the buried layer.
